(19) United States
(12) Patent Application Publication
(10) Pub. No.: US 2024/0113023 A1
(43) Pub. Date: Apr. 4, 2024

(54) Self-Aligned Wafer Backside Gate Signal with Airgap

(71) Applicant: International Business Machines Corporation, Armonk, NY (US)

(72) Inventors: Tao Li, Slingerlands, NY (US); Ruilong Xie, Niskayuna, NY (US); Nicolas Jean Loubet, Guilderland, NY (US); Julien Frougier, Albany, NY (US)

(21) Appl. No.: 17/955,974

(22) Filed: Sep. 29, 2022

(51) Int. Cl. H01L 23/528; H01L 21/768; H01L 21/8234; H01L 29/786

(52) U.S. Cl. CPC H01L 23/5286; H01L 21/76897; H01L 21/823431; H01L 29/78696

(57) ABSTRACT

A semiconductor device includes a backside power line located under a p-channel field effect transistor region and an n-channel field effect transistor region; a backside signal line located between the p-channel field effect transistor region and the n-channel field effect transistor region; and an airgap between the backside power line and the backside signal line.

### BACKGROUND

The exemplary embodiments described herein relate generally to semiconductor device design and integrated circuit design, and more specifically, to a self-aligned wafer backside gate signal with airgap.

It is desired to have low-k dielectrics surrounding signal lines to reduce resistive-capacitive delay. This disclosure describes a way to separate a power source/drain supply voltage to gate signal line by forming a self-aligned gate backside signal line with nearby airgaps.

### SUMMARY

In an aspect, a semiconductor device includes a backside power line located under a p-channel field effect transistor region and an n-channel field effect transistor region; a backside signal line located between the p-channel field effect transistor region and the n-channel field effect transistor region; and an airgap between the backside power line and the backside signal line.

In another aspect, a method of forming a semiconductor device includes forming at least a first source/drain supply voltage line and at least a second source/drain supply voltage line; depositing a first liner along a side of the at least the first source/drain supply voltage line; depositing the first liner along a side of the at least the second source/drain supply voltage line; depositing a second liner along the first liner that is along the side of the at least the first source/drain supply voltage line; depositing the second liner along the first liner that is along the side of the at least the second source/drain supply voltage line; depositing a third liner along the second liner that is deposited along the first liner that is along the side of the at least the first source/drain supply voltage line; depositing a third liner along the second liner that is deposited along the first liner that is along the side of the at least the second source/drain supply voltage line; filling metal between the at least first source/drain supply voltage line and the at least second source/drain supply voltage line to form at least one signal line; and removing the second liner to form at least one airgap between the at least first source/drain supply voltage line and the at least second source/drain supply voltage line.

In another aspect, a semiconductor device includes a first source/drain supply voltage line; a second source/drain supply voltage line; a signal line located between the first source/drain supply voltage line and the second source/drain supply voltage line; a first airgap between the first source/drain supply voltage line and the signal line; and a second airgap between the second source/drain supply voltage line and the signal line.

### BRIEF DESCRIPTION OF THE DRAWINGS

The foregoing and other aspects of exemplary embodiments are made more evident in the following Detailed Description, when read in conjunction with the attached Drawing Figures, wherein:

FIG. 1 depicts an example semiconductor structure;

FIG. 2 depicts forming a back end of line signal line metal layer 1 to metal layer x and bonding to a carrier wafer;

FIG. 3 depicts wafer flipping;

FIG. 4 depicts substrate removal, and stopping on an etch stop layer;

FIG. 5 depicts etch stop layer removal;

FIG. 6 depicts remaining substrate removal and backside interlayer dielectric deposition and chemical mechanical planarization;

FIG. 7 depicts backside contact patterning;

FIG. 8 depicts selective removal of a placeholder and backside contact metallization;

FIG. 9 depicts forming backside power lines;

FIG. 10 depicts backside source/drain supply voltage and signal line region opening;

FIG. 11 depicts backside interlayer dielectric pulling, an optical planarizing layer ash and first liner deposition;

FIG. 12 depicts second liner deposition and breakthrough application;

FIG. 13 depicts third liner deposition and breakthrough application;

FIG. 14 depicts backside gate signal line deposition and chemical mechanical planarization;

FIG. 15 depicts second liner pulling;

FIG. 16 depicts backside interlayer dielectric and a via to a first source/drain supply voltage, a second source/drain supply voltage, and signal;

FIG. 17 depicts remaining backside power delivery/distribution network formation; and

FIG. 18 is a logic flow diagram to fabricate a device, based on the examples described herein.

### DETAILED DESCRIPTION

The term “exemplary” is used herein to mean “serving as an example, instance, or illustration.” Any embodiment described herein as “exemplary” is not necessarily to be construed as preferred or advantageous over other embodiments. All of the embodiments described in this Detailed Description are exemplary embodiments provided to enable persons skilled in the art to make or use the invention and not to limit the scope of the invention which is defined by the claims.

It is desired to have low-k dielectrics surrounding signal lines to reduce resistive-capacitance delay. This disclosure describes a way to separate a source/drain supply voltage/source/drain supply voltage to gate signal line by forming a self-aligned gate backside signal line with nearby airgaps to achieve this purpose, namely having low-k dielectrics surrounding signal lines to reduce resistive-capacitance delay. This is an important option for backside power rail and backside power delivery/distribution network technology development.

A process flow includes forming a front end of line device with a dummy placeholder under an source/drain epitaxy and gate metal extension into shallow trench isolation; middle of line, back end of line formation, and carrier wafer bonding; flipping the wafer and removing a substrate; backside interlayer dielectric fill and chemical mechanical planarization; backside contact patterning, selective removal of the placeholder and backside contact metallization; forming backside power lines; patterning an n-channel field effect transistor and p-channel field effect transistor region where a gate signal line is needed, backside interlayer dielectric pulling; first liner deposition, second liner deposition and breakthrough application, third liner deposition and breakthrough application of both first and third liners; gate signal line metal filling and chemical mechanical planarization; second liner pulling and backside interlayer dielectric deposition for source/drain supply voltage and source/drain supply voltage and signal via formation; and forming the rest of the backside power delivery/distribution network.

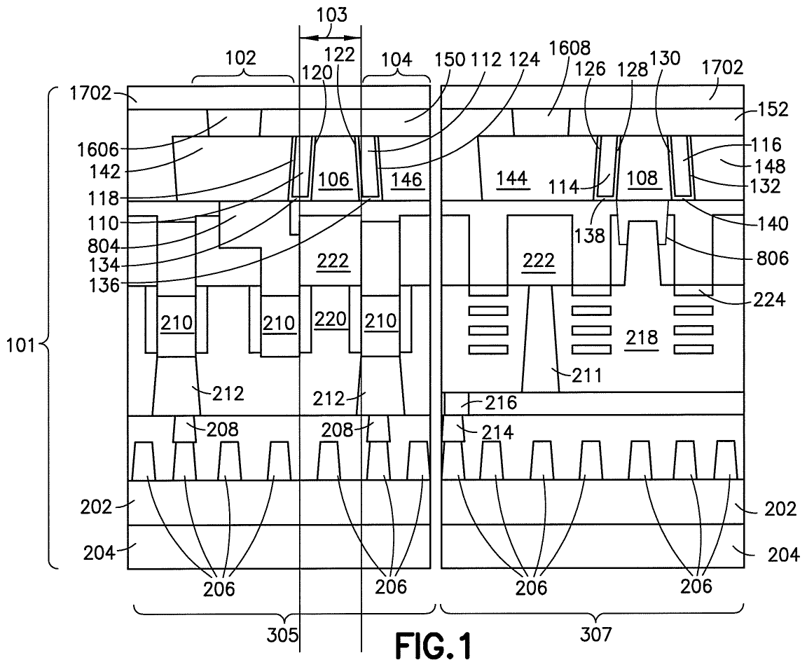

Referring to FIG. 1, the herein described semiconductor device comprises and is such that an airgap (110, 112, 114, 116) is between metal lines (142, 106, 146, 144, 108, 148) at the backside of the wafer 101. The backside power line (142, 146) is located under p-channel field effect transistor region 102 and n-channel field effect transistor region 104. The backside signal line 106 is located between the p-channel field effect transistor region 102 and the n-channel field effect transistor region 104. There is an airgap (110, 112, 114, 116) between the backside power line (142, 146, 144, 148) and backside signal line (106, 108). An airgap (110, 112, 114, 116) with two sidewalls covered with liner (118, 120, 122, 124, 126, 128, 130, 132) and bottom covered with liner (134, 136, 138, 140) is formed between the signal line (106, 108) and two nearby source/drain supply voltage lines. The source/drain supply voltage lines are given as 142 and 144, and the source/drain supply voltage lines are given as 146 and 148. The signal line (106, 108) has inverse trapezoid shape that follows the sidewall shape of the source/drain supply voltage and source/drain supply voltage line (142, 144, 146, 148). The top of the airgap (110, 112, 114, 116) is pinched off or sealed by backside interlayer dielectric (150, 152). There is also an n-channel field effect transistor to n-channel field effect transistor space 103 between the p-channel field effect transistor region 102 and the n-channel field effect transistor region 104.

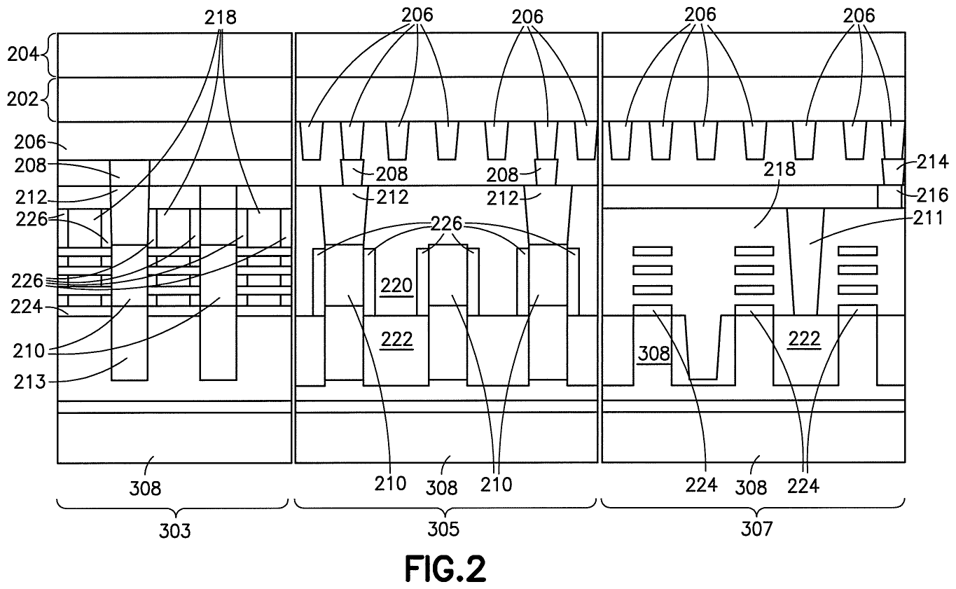

FIG. 1 further shows backside power delivery/distribution network (1702) joined to the source/drain supply voltage lines (142, 144) with vias (1606, 1608). Backside contact 804 joins source/drain supply voltage line 142 to source/drain 210, which source/drain 210 is partially encapsulated within interlayer dielectric 220, and backside contact 806 joins signal line 108 to high-K metal gate 218, which backside contacts (804, 806) are partially encapsulated within shallow trench isolation 222. Middle of line source/drain contacts (212) are connected to the source drains (210) and to the back end of line vias (208), which back end of line vias (208) couple the source drains (210) to metal layer 0 206, which metal layer 0 206 is joined to back end of line signal line metal layer 1 to metal layer x (202) which is joined to carrier wafer 204. The gate cut 211 is coupled to shallow trench isolation 222 and within high-K metal gate 218. Back end of line via 214 connects the metal layer 0 206 to the high-K metal gate 218 through middle of line gate contact 216. FIG. 1 depicts cross-sections 305 and 307 of the wafer 101. FIGS. 2 through 17 depict the process of forming the semiconductor device shown in FIG. 1.

FIG. 2 depicts forming a back end of line signal line metal layer 1 to metal layer x (202) and bonding to a carrier wafer (204). The back end of line signal line metal layer 1 to metal layer x (202) is joined to metal layer 0 signal line 206. Back end of line vias (208) connect the metal layer 0 206 to the plurality of source drains (210). Middle of line source/drain contacts (212) are connected to the source drains (210) and to the back end of line vias (208). The back end of line via 214 connects the metal layer 0 206 to the high-K metal gate 218 through middle of line gate contact 216. An interlayer dielectric 220 encapsulates the source/drains 210, and is connected to shallow trench isolation 222, which is connected to the silicon substrate 308. Bottom dielectric isolation 224 joins the silicon substrate 308 to the high-K metal gate 218. A spacer (226) is formed around some of the high-K metal gates 218, as well as some of the source/drains 210. Also shown in FIG. 2 is gate cut 211 within high-K metal gate 218, which gate cut 211 is connected to interlayer dielectric 220 and shallow trench isolation 222. A placeholder 213 is within the silicon substrate 308 under the source/drain 210 and bottom dielectric isolation 224.

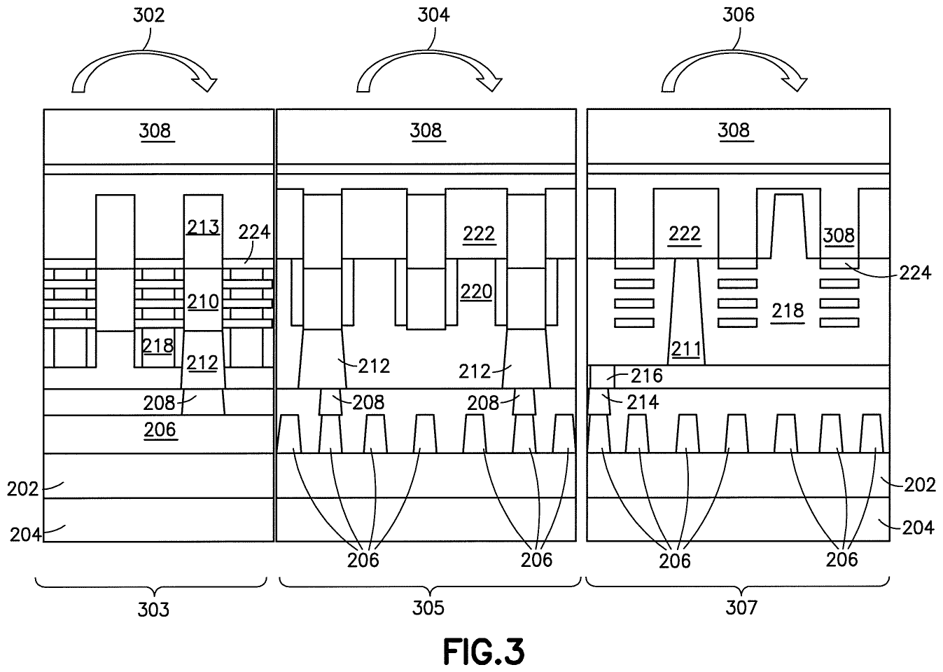

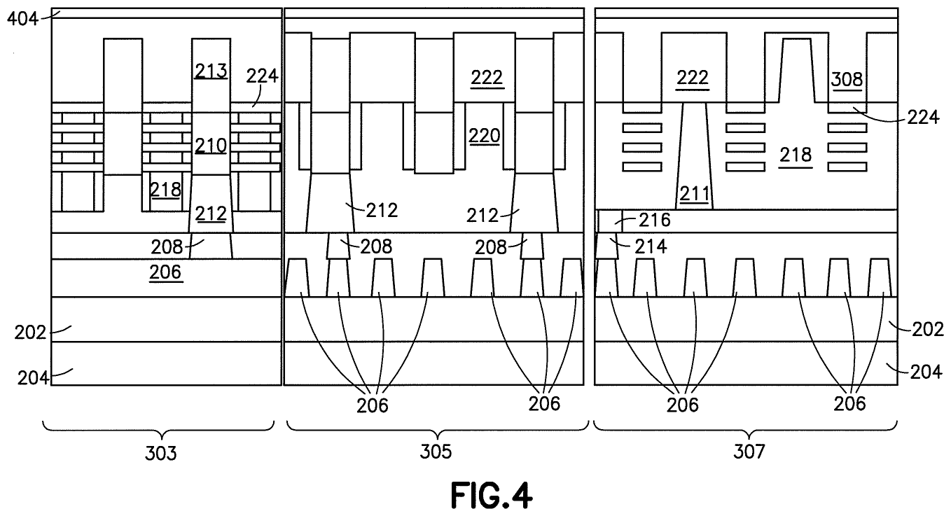

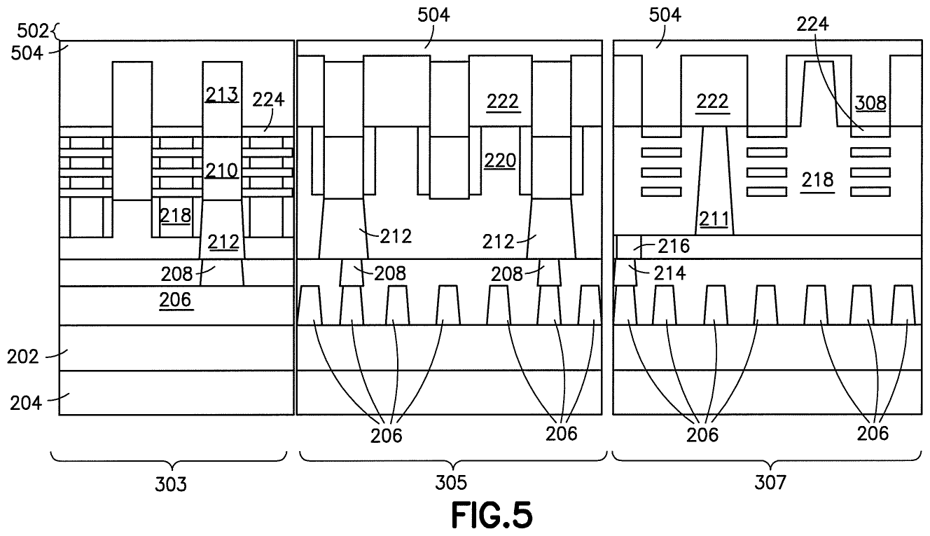

FIG. 3 depicts wafer flipping (302, 304, 306). In the example shown by FIG. 3, there are three separate flips, depicting the flip for each cross-section of the wafer 101. Wafer flip 302 depicts flipping of cross-section 303, flip 304 depicts flipping of cross-section 305, and flip 306 depicts flipping of cross-section 307. After the flipping (302, 304, 306), the back end of line signal line metal layer 1 to metal layer x (202) and carrier wafer (204) are near the bottom, and a portion of the silicon substrate 308 is near the top. FIG. 4 depicts substrate removal to remove silicon substrate 308, and stopping on an etch stop layer 404. FIG. 5 depicts removal of the etch stop layer 404 (removal depicted as 502) above remaining substrate 504 of silicon substrate 308.

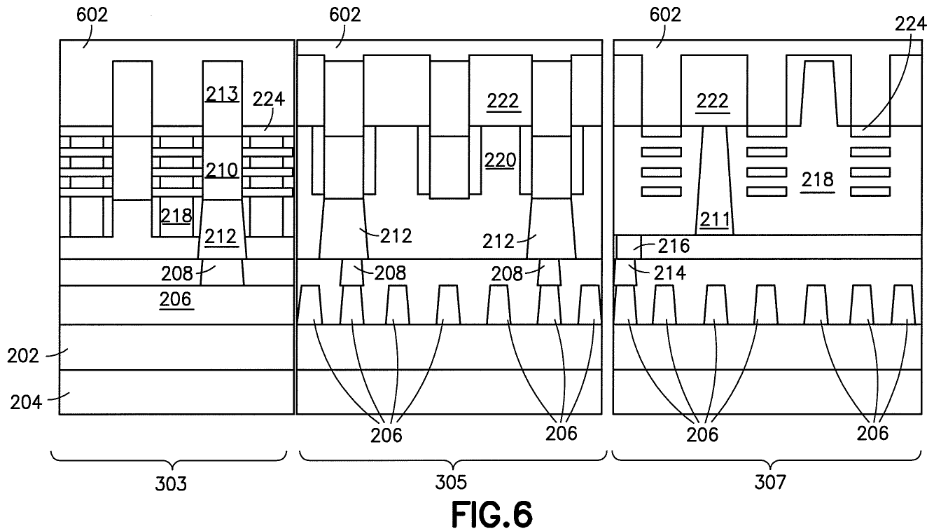

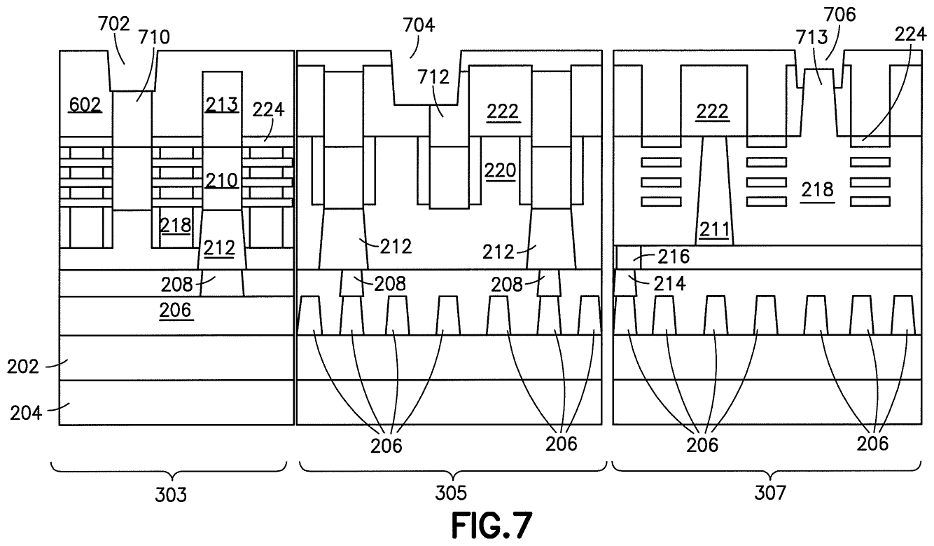

FIG. 6 depicts removal of the remaining substrate 504, and deposition of backside interlayer dielectric 602 to replace the remaining substrate 504 and chemical mechanical planarization. FIG. 7 depicts backside contact patterning to form etches 702, 704, and 706. The etches are formed at least partially within placeholders 710, 712 and around gate metal extension 713.

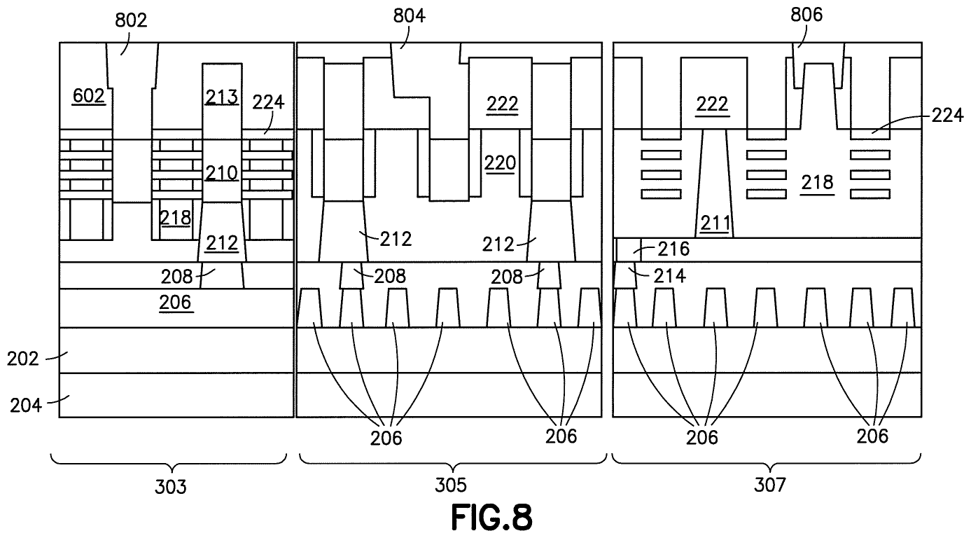

FIG. 8 depicts selective removal of the placeholder (710, 712), and backside source/drain contact metallization to form backside contacts (802, 804, 806). The backside contact 802 is formed at least partially within etch 702 and at least partially at the location of former placeholder 710. The backside contact 804 is formed at least partially within etch 704 and at least partially at the location of former placeholder 712. The backside contact 806 is formed at least partially within etch 706. FIG. 8 depicts also the asymmetric backside contact 804 and wrap around backside contact 806.

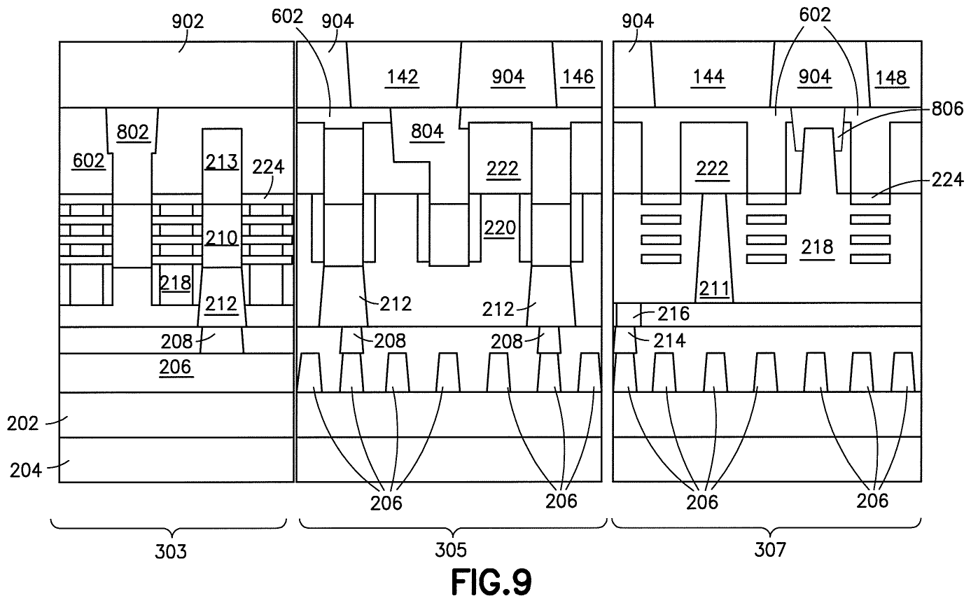

FIG. 9 depicts forming backside power lines. As shown, backside metal layer 0 source/drain supply voltage 902 is formed alongside backside interlayer dielectric 602 and backside source/drain contact 802. The source/drain supply voltage 142 is formed at least partially alongside backside interlayer dielectric 602 and backside source/drain contact 804. The source/drain supply voltage 146, source/drain supply voltage 144, and source/drain supply voltage 148 are formed alongside backside interlayer dielectric 602. There is a backside interlayer dielectric 904 applied between source/drain supply voltage 142 and source/drain supply voltage 146, and between source/drain supply voltage 144 and source/drain supply voltage 148. The additional backside interlayer dielectric 904 is deposited on top of backside interlayer dielectric 602, as shown. Then patterning is applied to backside interlayer dielectric 904 to open a source/drain supply voltage, source/drain supply voltage trench. Then metal is filled and chemical mechanical planarization is performed to flash on top of the additional backside interlayer dielectric 904.

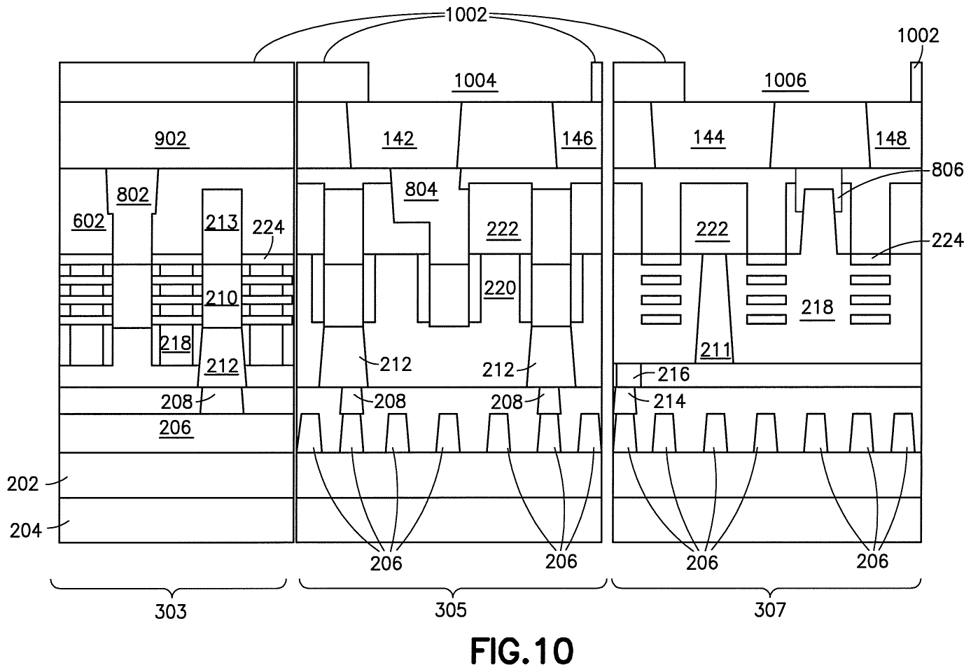

FIG. 10 depicts backside source/drain supply voltage and source/drain supply voltage and signal line region opening. Material 1002 is applied alongside backside metal layer 0 source/drain supply voltage 902, and at least partially alongside source/drain supply voltage 142, source/drain supply voltage 146, source/drain supply voltage 144, and source/drain supply voltage 148, as shown. Signal line region openings are given as 1004 and 1006.

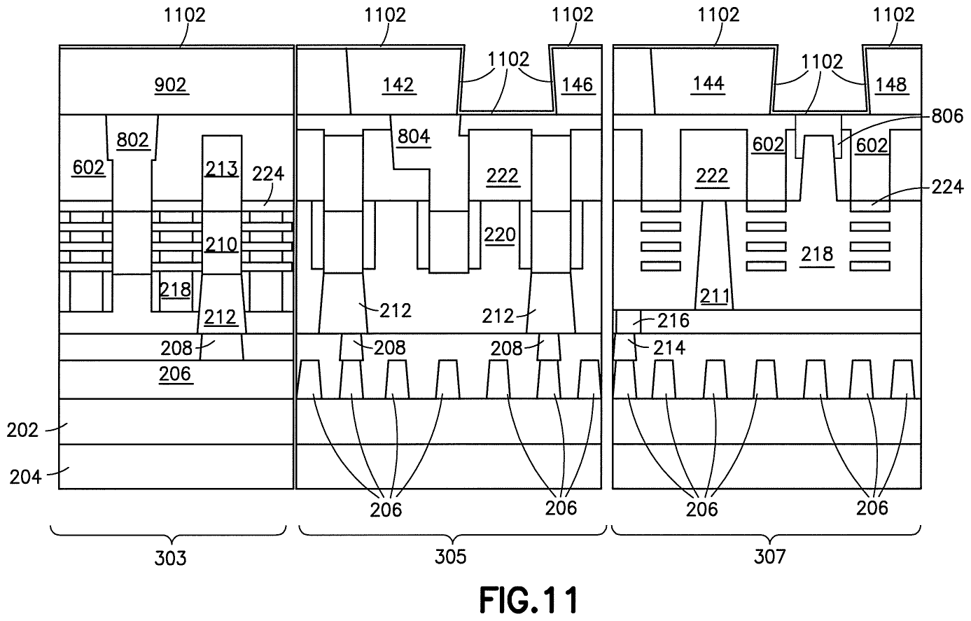

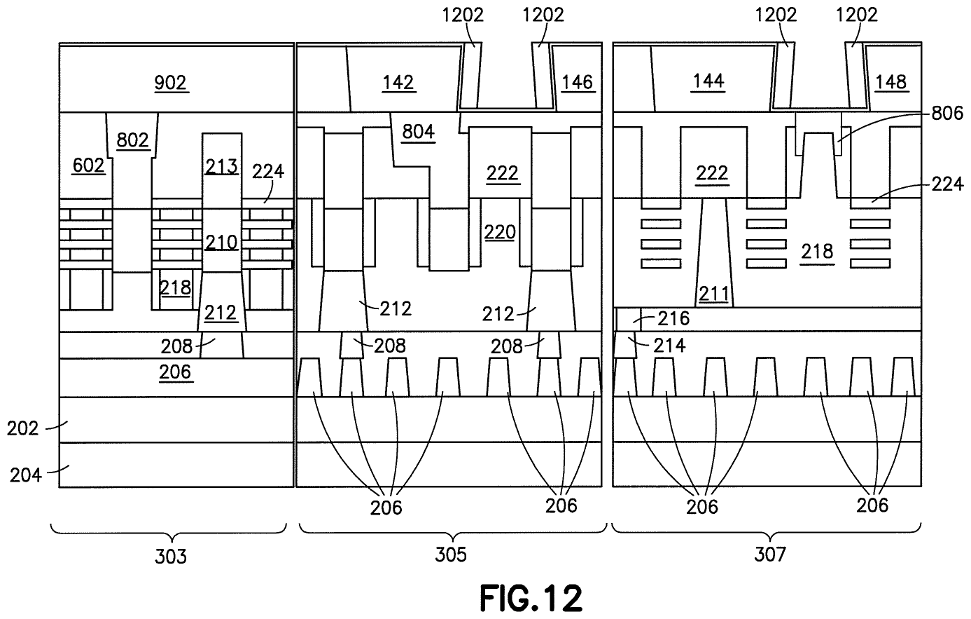

FIG. 11 depicts backside interlayer dielectric pulling, material 1002 removal and first liner deposition. As shown in FIG. 11, liner 1102 is applied at least partially alongside backside metal layer 0 source/drain supply voltage 902, backside interlayer dielectric 904, source/drain supply voltage 142, backside source/drain contact 804, backside interlayer dielectric 602, source/drain supply voltage 146, source/drain supply voltage 144, backside source/drain contact 806, and source/drain supply voltage 148. FIG. 12 depicts deposition of second liner 1202 and breakthrough application. The second liner 1202 is applied along the liner 1102 along a side of source/drain supply voltage 142, source/drain supply voltage 146, source/drain supply voltage 144, source/drain supply voltage 148, backside interlayer dielectric 602 and along backside source/drain contact 804.

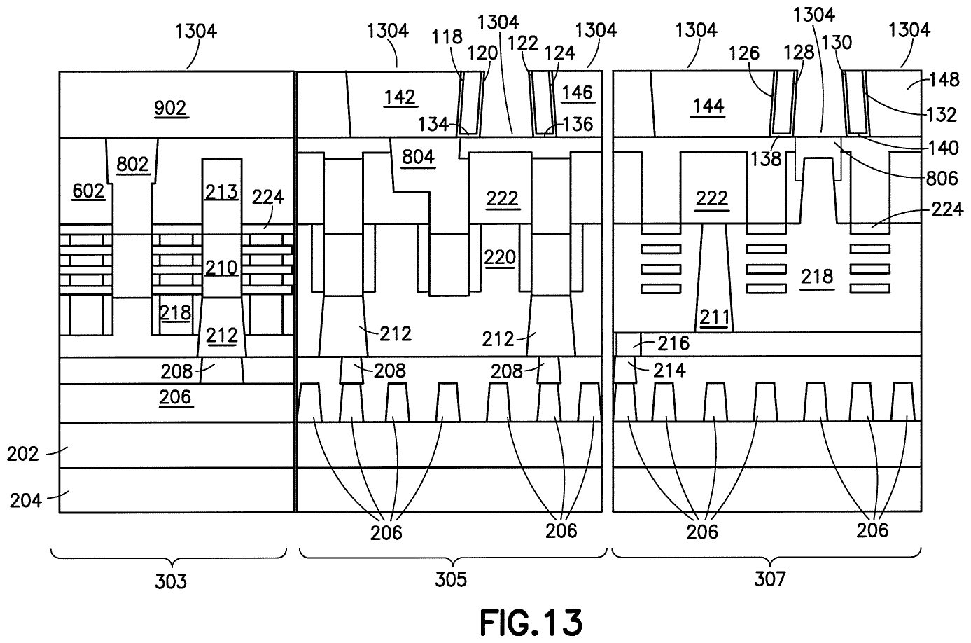

FIG. 13 depicts third liner deposition and breakthrough. As shown in FIG. 13, liner (120, 122, 128, 130) is applied alongside the second liner 1202 opposite the side the liner 1102 contacts source/drain supply voltage 142, source/drain supply voltage 146, source/drain supply voltage 144, and source/drain supply voltage 148. FIG. 13 also shows removal of portions of liner 1102 (refer to 1304). With this formation, portions of liner 1102 now become liner (118, 134, 136, 124, 126, 138, 140, 132).

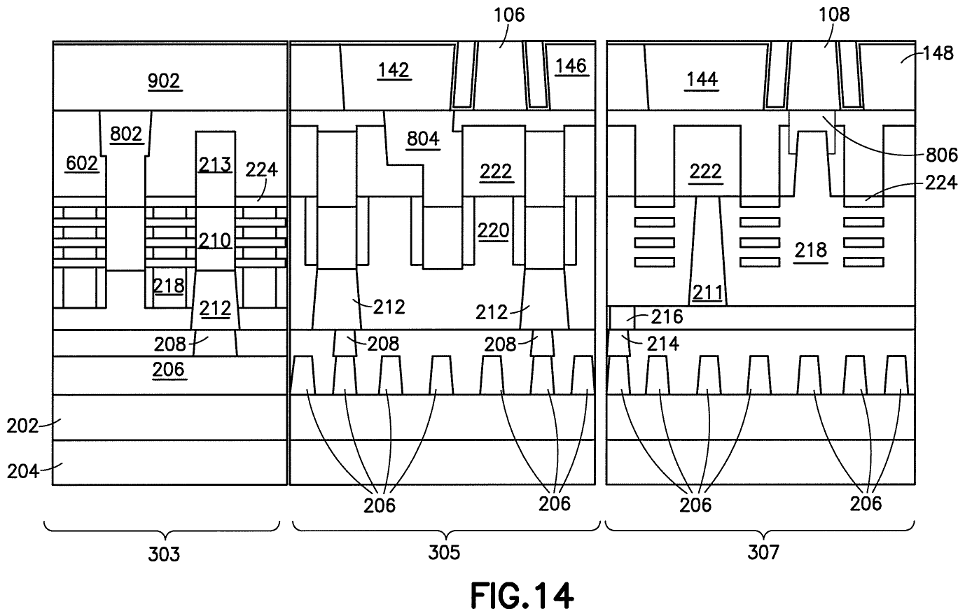

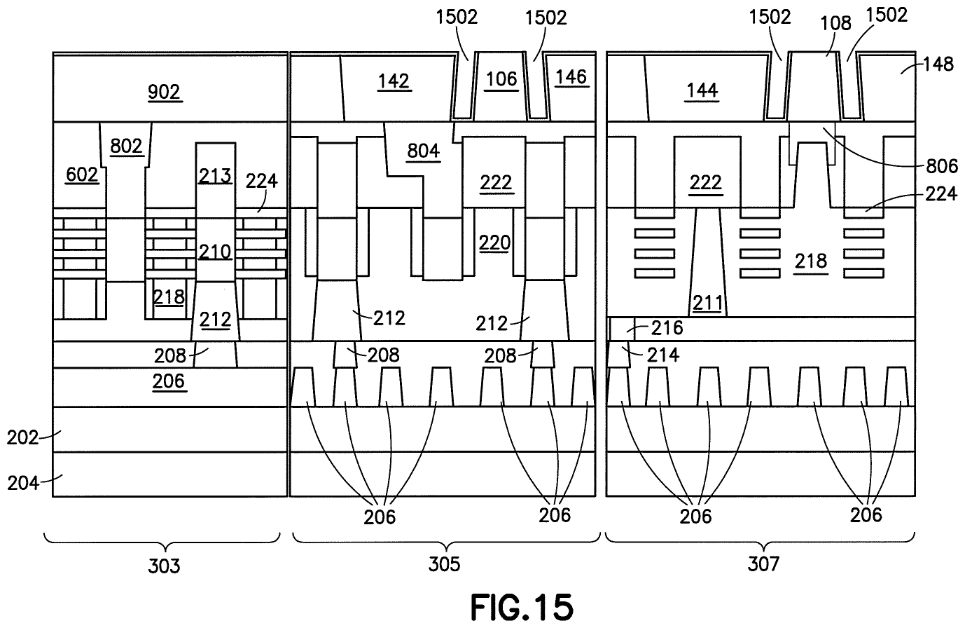

FIG. 14 depicts backside gate signal line deposition and chemical mechanical planarization. In particular, FIG. 14 shows formation of signal lines 106 and 108. The separation between backside signal line 106 (as shown in FIG. 14) and backside source/drain contact 804 is depicted as being good. FIG. 15 depicts pulling of the second liner 1202, forming regions 1502 that are to become the airgaps (110, 112, 114, 116).

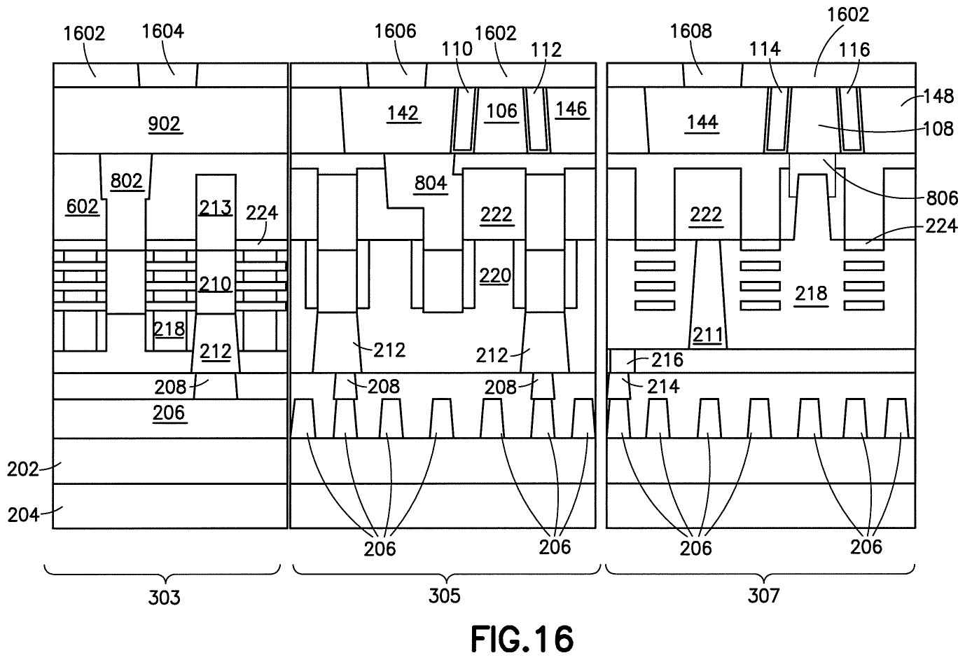

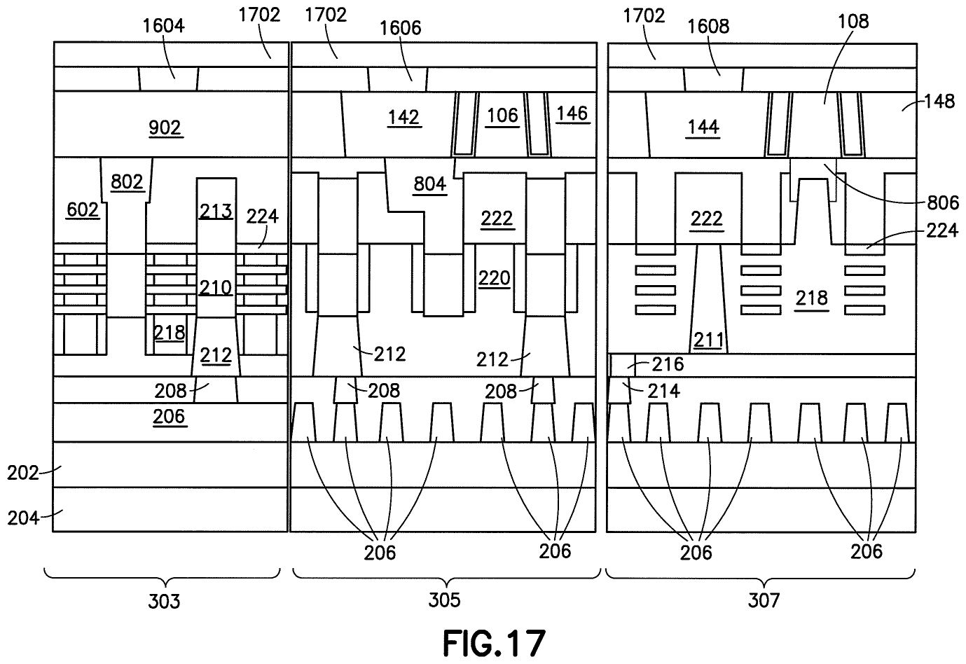

FIG. 16 depicts application of a backside interlayer dielectric layer 1602 and formation of vias (1604, 1606, 1608) that connect to source/drain supply voltage (902, 142, 144). The backside interlayer dielectric layer 1602 is formed over source/drain supply voltage 146 and source/drain supply voltage 148. The backside interlayer dielectric layer 1602 is formed over the signal lines (106, 108) and over regions 1502 to seal the airgaps (110, 112, 114, 116). As shown in FIG. 16, via 1604 is formed to contact backside metal layer 0 source/drain supply voltage 902, via 1606 is formed to contact source/drain supply voltage 142, and via 1608 is formed to contact source/drain supply voltage 144. FIG. 17 depicts remaining backside power delivery/distribution network formation (1702) over the vias (1604, 1606, 1608) and backside interlayer dielectric layer 1602.

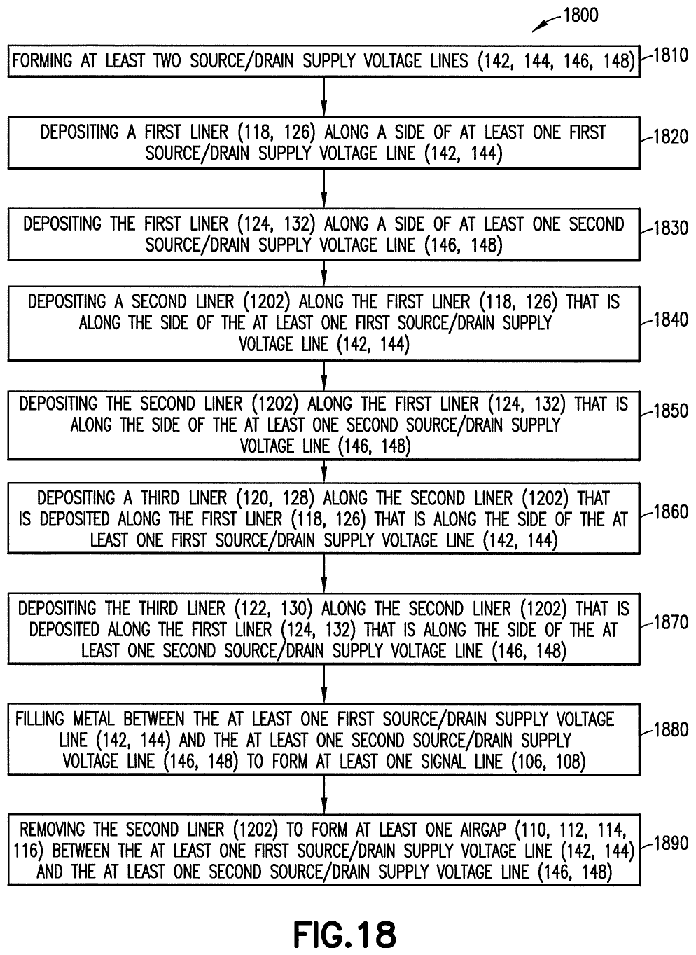

FIG. 18 is a logic flow diagram 1800 to fabricate a device, based on the examples described herein. At 1810, the method includes forming at least two source/drain supply voltage lines (142, 144. 146, 148). At 1820, the method includes depositing a first liner (118, 126) along a side of at least one first source/drain supply voltage line (142, 144). At 1830, the method includes depositing the first liner (124, 132) along a side of at least one second source/drain supply voltage line (146, 148). At 1840, the method includes depositing a second liner (1202) along the first liner (118, 126) that is along the side of the at least one first source/drain supply voltage line (142, 144). At 1850, the method includes depositing the second liner (1202) along the first liner (124, 132) that is along the side of the at least one second source/drain supply voltage line (146, 148). At 1860, the method includes depositing a third liner (120, 128) along the second liner (1202) that is deposited along the first liner (118, 126) that is along the side of the at least one first source/drain supply voltage line (142, 144). At 1870, the method includes depositing the third liner (122, 130) along the second liner (1202) that is deposited along the first liner (124, 132) that is along the side of the at least one second source/drain supply voltage line (146, 148). At 1880, the method includes filling metal between the at least one first source/drain supply voltage line (142, 144) and the at least one second source/drain supply voltage line (146, 148) to form at least one signal line (106, 108). At 1890, the method includes removing the second liner (1202) to form at least one airgap (110, 112, 114, 116) between the at least one first source/drain supply voltage line (142, 144) and the at least one second source/drain supply voltage line (146, 148).

Referring now to all the Figures, in one exemplary embodiment, a semiconductor device includes a backside power line located under a p-channel field effect transistor region and an re-channel field effect transistor region; a backside signal line located between the p-channel field effect transistor region and the n-channel field effect transistor region; and an airgap between the backside power line and the backside signal line.

The airgap may include at least two sidewalls covered with a liner, and a bottom covered with the liner. The airgap may be formed between a signal line and a source/drain supply voltage line. The semiconductor device may further include a signal line; a first source/drain supply voltage line comprising at least one sidewall; and a second source/drain supply voltage line comprising at least one sidewall. The signal line may have an inverse trapezoid shape that follows a shape of the at least one sidewall of the first source/drain supply voltage line, and a shape of the at least one sidewall of the second source/drain supply voltage line. The semiconductor device may further include a layer of interlayer dielectric that covers and seals a top of the airgap.

In another embodiment, a method of forming a semiconductor device includes forming at least a first source/drain supply voltage line and at least a second source/drain supply voltage line; depositing a first liner along a side of the at least the first source/drain supply voltage line; depositing the first liner along a side of the at least the second source/drain supply voltage line; depositing a second liner along the first liner that is along the side of the at least the first source/drain supply voltage line; depositing the second liner along the first liner that is along the side of the at least the second source/drain supply voltage line; depositing a third liner along the second liner that is deposited along the first liner that is along the side of the at least the first source/drain supply voltage line; depositing a third liner along the second liner that is deposited along the first liner that is along the side of the at least the second source/drain supply voltage line; filling metal between the at least first source/drain supply voltage line and the at least second source/drain supply voltage line to form at least one signal line; and removing the second liner to form at least one airgap between the at least first source/drain supply voltage line and the at least second source/drain supply voltage line.

The method may further include depositing the first liner along an interlayer dielectric between the at least first source/drain supply voltage line and the at least the second source/drain supply voltage line; wherein the second liner is deposited along at least a portion of the first liner deposited along the interlayer dielectric between the at least first source/drain supply voltage line and the at least second source/drain supply voltage line. A first portion of the first liner deposited along the interlayer dielectric may contact the at least the first source/drain supply voltage line; and a second portion of the first liner deposited along the interlayer dielectric may contact the at least the second source/drain supply voltage line. The method may further include patterning a p-channel field effect transistor region and an n-channel field effect transistor region for the signal line. The method may further include forming an interlayer dielectric over the at least one airgap to seal the at least one airgap. The method may further include forming a backside interconnect layer for a backside power delivery network; and forming at least one via to join the at least one source/drain supply voltage line to the backside interconnect layer. The method may further include forming the at least one signal line to have an inverse trapezoid shape that follows a shape of the side of the at least first source/drain supply voltage line, and the side of the at least second source/drain supply voltage line.

In another embodiment, a semiconductor device includes a first source/drain supply voltage line; a second source/drain supply voltage line; a signal line located between the first source/drain supply voltage line and the second source/drain supply voltage line; a first airgap between the first source/drain supply voltage line and the signal line; and a second airgap between the second source/drain supply voltage line and the signal line.

The first airgap may include two sidewalls covered with a liner and a bottom covered with the liner, and the second airgap may include two sidewalls covered with the liner and a bottom covered with the liner. The signal line may have a trapezoid shape that follows a shape of at least one sidewall of the first source/drain supply voltage line and a shape of at least one sidewall of the second source/drain supply voltage line. The semiconductor device may further include an interlayer dielectric that seals the first airgap and the second airgap. The first source/drain supply voltage line may be located under a p-channel field effect transistor region, and the second source/drain supply voltage line may be located under an n-channel field effect transistor region. The signal line may be located between a p-channel field effect transistor region and an n-channel field effect transistor region.

The memory(ies) as described herein may be implemented using any suitable data storage technology, such as semiconductor based memory devices, flash memory, magnetic memory devices and systems, optical memory devices and systems, non-transitory memory, transitory memory, fixed memory and removable memory. The memory(ies) may comprise a database for storing data.

As used herein, circuitry may refer to the following: (a) hardware circuit implementations, such as implementations in analog and/or digital circuitry, and (b) combinations of circuits and software (and/or firmware), such as (as applicable): (i) a combination of processor(s) or (ii) portions of processor(s)/software including digital signal processor(s), software, and memory(ies) that work together to cause an apparatus to perform various functions, and (c) circuits, such as a microprocessor(s) or a portion of a microprocessor(s), that require software or firmware for operation, even if the software or firmware is not physically present. As a further example, as used herein, circuitry would also cover an implementation of merely a processor (or multiple processors) or a portion of a processor and its (or their) accompanying software and/or firmware. Circuitry would also cover, for example and if applicable to the particular element, a baseband integrated circuit or applications processor integrated circuit for a mobile phone or a similar integrated circuit in a server, a cellular network device, or another network device.

In the foregoing description, numerous specific details are set forth, such as particular structures, components, materials, dimensions, processing steps, and techniques, in order to provide a thorough understanding of the exemplary embodiments disclosed herein. However, it will be appreciated by one of ordinary skill of the art that the exemplary embodiments disclosed herein may be practiced without these specific details. Additionally, details of well-known structures or processing steps may have been omitted or may have not been described in order to avoid obscuring the presented embodiments.

The description of the present invention has been presented for purposes of illustration and description, but is not intended to be exhaustive or limiting in the form disclosed. Many modifications and variations will be apparent to those of ordinary skill in the art without departing from the scope of the invention. The embodiments were chosen and described in order to best explain the principles of the invention and the practical applications, and to enable others of ordinary skill in the art to understand the invention for various embodiments with various modifications as are suited to the particular uses contemplated.

What is claimed is:

1. A semiconductor device comprising:
a backside power line located under a p-channel field effect transistor region and an n-channel field effect transistor region;
a backside signal line located between the p-channel field effect transistor region and the n-channel field effect transistor region; and
an airgap between the backside power line and the backside signal line.

2. The semiconductor device of claim 1, wherein the airgap comprises at least two sidewalls covered with a liner, and a bottom covered with the liner.

3. The semiconductor device of claim 1, wherein the airgap is formed between a signal line and a source/drain supply voltage line.

4. The semiconductor device of claim 1, further comprising:
a signal line;
a first source/drain supply voltage line comprising at least one sidewall; and
a second source/drain supply voltage line comprising at least one sidewall.

5. The semiconductor device of claim 4, wherein the signal line has an inverse trapezoid shape that follows a shape of the at least one sidewall of the first source/drain supply voltage line, and a shape of the at least one sidewall of the second source/drain supply voltage line.

6. The semiconductor device of claim 1, further comprising a layer of interlayer dielectric that covers and seals a top of the airgap.

7. A method of forming a semiconductor device, comprising:
forming at least a first source/drain supply voltage line and at least a second source/drain supply voltage line;
depositing a first liner along a side of the at least the first source/drain supply voltage line;
depositing the first liner along a side of the at least the second source/drain supply voltage line;
depositing a second liner along the first liner that is along the side of the at least the first source/drain supply voltage line;
depositing the second liner along the first liner that is along the side of the at least the second source/drain supply voltage line;
filling metal between the at least first source/drain supply voltage line and the at least second source/drain supply voltage line to fouls at least one signal line; and
removing the second liner to form at least one airgap between the at least first source/drain supply voltage line and the at least second source/drain supply voltage line.

8. The method of claim 7, further comprising:
depositing the first liner along an interlayer dielectric between the at least first source/drain supply voltage line and the at least the second source/drain supply voltage line;
wherein the second liner is deposited along at least a portion of the first liner deposited along the interlayer dielectric between the at least first source/drain supply voltage line and the at least second source/drain supply voltage line.

9. The method of claim 8, wherein:
a first portion of the first liner deposited along the interlayer dielectric contacts the at least the first source/drain supply voltage line; and
a second portion of the first liner deposited along the interlayer dielectric contacts the at least the second source/drain supply voltage line.

10. The method of claim 7, further comprising:
patterning a p-channel field effect transistor region and an n-channel field effect transistor region for the signal line.

11. The method of claim 7, further comprising:
forming an interlayer dielectric over the at least one airgap to seal the at least one airgap.

12. The method of claim 7, further comprising:
forming a backside interconnect layer for a backside power delivery network; and
forming at least one via to join the at least one first source/drain supply voltage line or the at least one second source/drain supply voltage line to the backside interconnect layer.

13. The method of claim 7, further comprising:
depositing a third liner along the second liner that is deposited along the first liner that is along the side of the at least first source/drain supply voltage line; and
depositing the third liner along the second liner that is deposited along the first liner that is along the side of the at least second source/drain supply voltage line.

14. The method of claim 7, further comprising:
forming the at least one signal line to have an inverse trapezoid shape that follows a shape of the side of the at least first source/drain supply voltage line, and the side of the at least second source/drain supply voltage line.

15. A semiconductor device comprising:
a first source/drain supply voltage line;
a second source/drain supply voltage line;
a signal line located between the first source/drain supply voltage line and the second source/drain supply voltage line;
a first airgap between the first source/drain supply voltage line and the signal line; and
a second airgap between the second source/drain supply voltage line and the signal line.

16. The semiconductor device of claim 15, wherein the first airgap comprises two sidewalls covered with a liner and a bottom covered with the liner, and the second airgap comprises two sidewalls covered with the liner and a bottom covered with the liner.

17. The semiconductor device of claim 15, wherein the signal line has a trapezoid shape that follows a shape of at least one sidewall of the first source/drain supply voltage line and a shape of at least one sidewall of the second source/drain supply voltage line.

18. The semiconductor device of claim 15, further comprising an interlayer dielectric that seals the first airgap and the second airgap.

19. The semiconductor device of claim 15, wherein the first source/drain supply voltage line is located under a p-channel field effect transistor region, and the second source/drain supply voltage line located under an n-channel field effect transistor region.

20. The semiconductor device of claim 15, wherein the signal line is located between a p-channel field effect transistor region and an n-channel field effect transistor region.
